(19) United States
(12) Patent Application Publication
(10) Pub. No.: US 2025/0370045 A1
(43) Pub. Date: Dec. 4, 2025

(54) Arrester Monitoring System with Failure Prediction

(71) Applicant: Southern States, LLC, Hampton, GA (US)

(72) Inventors: Hua Fan, Cumming, GA (US); Jiyuan Fan, Duluth, GA (US)

(21) Appl. No.: 19/227,416

(22) Filed: Jun. 3, 2025

Related U.S. Application Data
(60) Provisional application No. 63/655,170, filed on Jun. 3, 2024.

(51) Int. Cl. G01R 31/327; G01N 25/72; H02H 5/04; H02H 9/04

(52) U.S. Cl. CPC G01R 31/3277; G01N 25/72; H02H 5/047; H02H 9/04

(57) ABSTRACT

An arrester monitoring system includes a surge arrester with multiple metal oxide varistor (MOV) disks and a current surge detector positioned around the ground wire to detect current surges and generate electrical current measurements. A thermal camera captures thermal images of the surge arrester, and a local controller connected to both the current surge detector and thermal camera detects current surge events and activates the thermal camera accordingly. The local controller analyzes the thermal images to identify thermal imbalances indicative of failed MOV disks. An artificial intelligence-based failure prediction system processes data from the thermal camera and current surge detector to predict the likelihood of surge arrester failure. A communication interface transmits thermal data and failure predictions to a maintenance control center to facilitate scheduling of preventative maintenance.

### REFERENCE TO RELATED APPLICATION

This application claims the benefit of U.S. Provisional Pat. App. Ser. No. 63/655,170 filed Jun. 3, 2024, the contents of which are hereby incorporated by reference.

### TECHNICAL FIELD

The present invention is directed to systems and methods for monitoring the condition of surge arresters, and more particularly to an arrester monitoring system utilizing thermal imaging, current surge detection, and artificial intelligence for failure prediction and maintenance scheduling.

### BACKGROUND

The disclosed approach to monitoring arrester health condition is based on thermal-camara monitoring triggered by surge strike current and voltage measurement. When a strong surge striking occurs near an arrester, either due to a switch operation or a lightning striking, it will result in a significant current increase through the arrester, which will lead to the arrester's temperature increasing. For a healthy arrester, the temperature increase along the arrester will be fairly in a uniform manner. This is because the MOV arresters includes many pieces of MOV disks connected in serial and each of the disks absorbs nearly the same amount of r/² energy. For a healthy MOV disk, its resistance of r will decrease exponentially with its voltage increases in a strongly non-linear way, resulting in a dramatically increased current, once the voltage exceeds the turn-on level.

Surge arrester monitoring systems have traditionally relied on electrical measurements to assess the condition of metal oxide varistor (MOV) disks within surge arresters. Current surge detectors positioned around ground wires have been employed to detect transient current surges, providing electrical signals indicative of surge events.

These systems typically focus on capturing and analyzing electrical parameters such as surge magnitude and frequency to infer the health status of the arrester components. However, such electrical-only monitoring approaches may not fully capture the onset of physical degradation or localized failures within the MOV disks.

Thermal imaging techniques have also been applied in arrester monitoring to identify abnormal temperature distributions that may signal deteriorating or failed MOV disks. Thermal cameras can capture infrared images of surge arresters, enabling visual detection of hotspots or thermal imbalances that correspond to internal faults. Some systems integrate thermal imaging with periodic inspections or manual activation, allowing maintenance personnel to identify potential failures before catastrophic arrester breakdowns occur. Nonetheless, these implementations often operate independently of electrical surge detection and may lack real-time responsiveness to surge events.

More recently, efforts have been made to combine electrical surge detection with thermal imaging to enhance arrester diagnostics. Systems have been developed wherein current surge detectors trigger thermal imaging devices to capture arrester temperature profiles during or immediately after surge events. This integration aims to correlate electrical surge data with thermal anomalies for improved fault detection accuracy. Additionally, some approaches incorporate data analysis algorithms to interpret combined electrical and thermal data, though these analyses are generally rule-based or threshold-driven rather than employing advanced predictive models. Communication of monitoring data to maintenance centers has been facilitated through wired or wireless interfaces, enabling remote condition assessment and maintenance scheduling.

These previous approaches have utilized electrical surge detection, thermal imaging, and data communication in arrester monitoring, with some integration between electrical and thermal data analysis. However, none of these approaches have provided a comprehensive solution that combines the features described in this disclosure.

### SUMMARY

In some aspects, the techniques described herein relate to an arrester monitoring system, including a surge arrester including a plurality of metal oxide varistor (MOV) disks. A current surge detector is positioned around a ground wire of the surge arrester, that is configured to detect current surges and generate an electrical current measurement. A thermal camera is configured to capture thermal images of the surge arrester. A local controller is operatively connected to the current surge detector and the thermal camera. The local controller is configured to detect a current surge event based on the electrical current measurement, activate the thermal camera to capture thermal images of the surge arrester in response to the current surge event, and analyze the thermal images to detect thermal imbalances indicative of one or more failed MOV disks. An artificial intelligence (AI)-based failure prediction system is configured to analyze data from the thermal camera and the current surge detector to predict a likelihood of failure of the surge arrester. A communication interface is configured to transmit thermal data and failure predictions to a maintenance control center for scheduling preventative maintenance of the surge arrester.

In some aspects, the techniques described herein relate to an arrester monitoring system, wherein the current surge detector is further configured to detect leakage current through the surge arrester and transmit leakage current data to the local controller.

In some aspects, the techniques described herein relate to a substation for an electric power system, including a protective equipment including a surge arrester having a plurality of metal oxide varistor (MOV) disks, a current surge detector positioned around a ground wire of the surge arrester, configured to detect current surges and generate a current measurement; a thermal camera configured to capture thermal images of the surge arrester; a local controller operatively connected to the current surge detector and the thermal camera. The local controller is configured to detect a current surge event based on the current measurement, activate the thermal camera to capture thermal images of the surge arrester in response to the current surge event, and analyze with an artificial intelligence (Al)-based failure prediction system the thermal images to detect thermal imbalances indicative of failed or failing MOV disks and a current surge detector to predict a likelihood of failure of the surge arrester. A ground grid is configured to safely discharge excess energy from the surge arrester into ground.

In some aspects, the techniques described herein relate to a substation, wherein the thermal camera is a multi-use device configured to monitor other equipment or surveil an area around the surge arrester when not capturing thermal images of the surge arrester.

In some aspects, the techniques described herein relate to a substation, wherein the artificial intelligence (AI)-based failure prediction system is configured to retrieve historical arrester data from a database to enhance failure prediction accuracy.

In some aspects, the techniques described herein relate to a method for operating an arrester monitoring and maintenance system, including providing a surge arrester including a plurality of metal oxide varistor (MOV) disks, detecting a current surge event through the surge arrester using a current surge detector positioned around a ground wire of the surge arrester, activating a thermal camera to capture thermal images of the surge arrester in response to the current surge event, analyzing the thermal images to detect thermal imbalances indicative of failed MOV disks, transmitting thermal data and failure predictions to a maintenance control center, and scheduling preventative maintenance of the surge arrester based on the transmitted thermal data and failure predictions to replace or repair the surge arrester prior to complete failure.

In some aspects, the techniques described herein relate to a method, further including using the thermal camera as a multi-use device to monitor other equipment or surveil ground adjacent the surge arrester when not capturing thermal images of the surge arrester.

### BRIEF DESCRIPTION OF THE FIGURES

The numerous advantages of the invention may be better understood with reference to the accompanying figures in which:

FIG. 1 and FIG. 2 are schematics of a representative arrester early fault detection system.

FIG. 3 is a conceptual illustration of a thermal image of a representative of a failed arrester indication on an arrester that may be sensed by thermal camera.

FIG. 4A is a conceptual illustration of a thermal image of a representative of an arrester having a sequence of multiple MOV's with excessive arrester current leak indication.

FIG. 4B is a conceptual illustration of a thermal image of a representative of a potential future arrester failure indication on an arrester.

FIG. 5 is a flow chart illustrating a transient monitoring routine implemented by the arrester early fault detection and preventive maintenance system.

FIG. 6 is a flow chart illustrating a leakage monitoring routine implemented by the arrester early fault detection and preventive maintenance system.

### DESCRIPTION

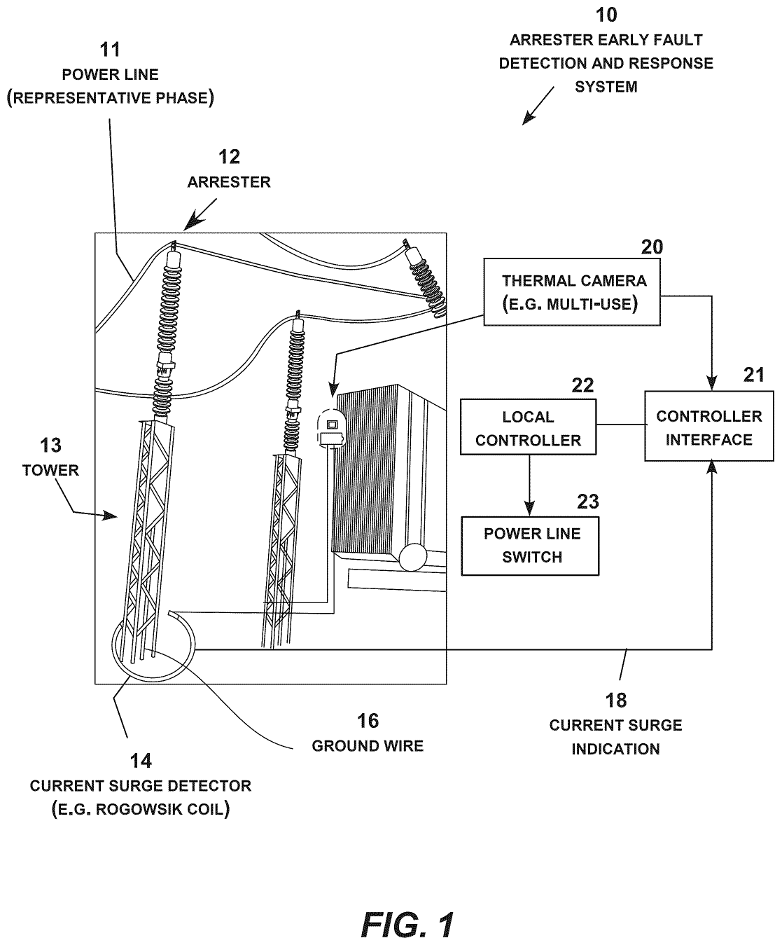

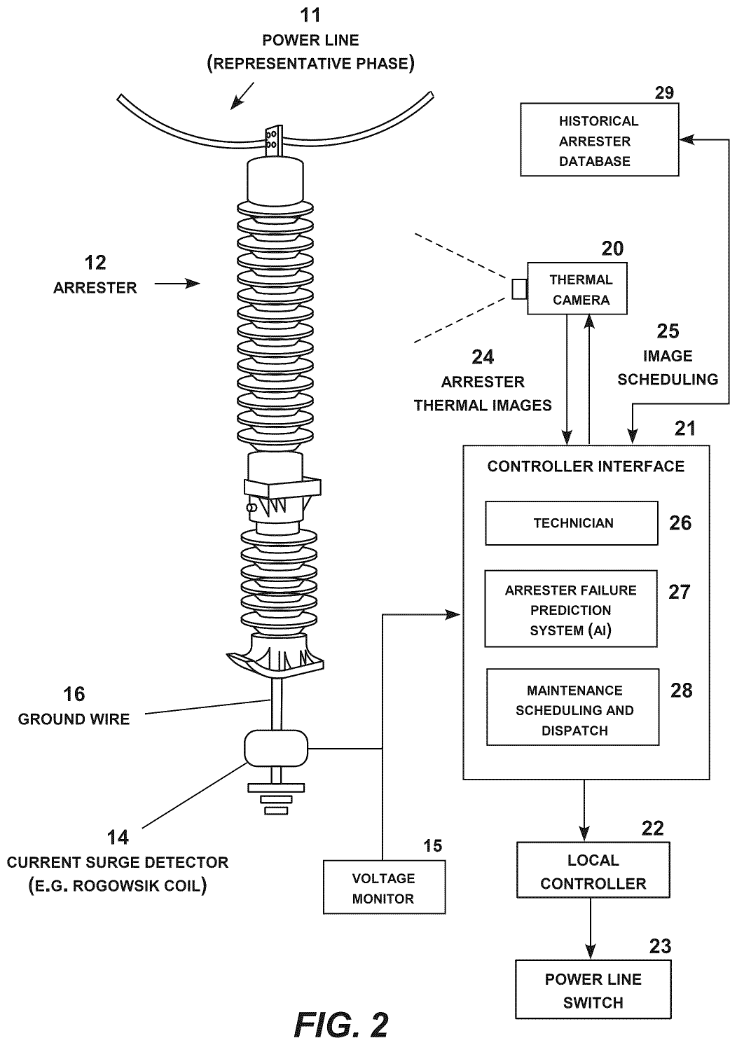

FIG. 1 and FIG. 2 are a schematics of a representative arrester early fault detection system 10 (also referred to as a substation for an electric power system) including a power line 11 connected to a selected arrester 12, tower 13 and a current surge detector (e.g., Rogowski coil) 14 positioned around a ground wire 16 of the selected arrester 12. Arrester 12 (also referred to as protective equipment) includes many metal oxide varistor (MOV) disks connected or stacked in series. Current surge detector 14 may also generate an electrical current measurement. A ground grid may be coupled with current surge detector and is configured to safely discharge excess energy from the surge arrester 12 into the ground The current surge detector 14 produces an electrical current measurement and/or an electrical current surge indication 18, which is transmitted to a controller interface 21 that controls a thermal camera (or any a multi-use device) 20. A voltage monitor indication 15 may be provided with current surge indication to controller interface 21. The controller interface 21 controls the thermal camera 20 according to programmed instructions. For example, controller interface 21 may direct the thermal camera 20 to take or capture a thermal reading of a selected arrester 12 in response to detecting a current surge indication 18 on current surge detector 14 occurring through the selected arrester 12. As the temperature rise caused by the current surge event typically takes on the order of an hour to dissipate, the controller interface 21 may cause the thermal camera 20 to take an extended reading of the selected arrester 12 by capturing one or more thermal images, such as over 30 minutes, in response to a current surge event.

Controller interface 21 may be coupled via local controller 22 to power line switch 23. In response to current surge indication 18 and/or one or more indications from thermal camera 20 (e.g. an indication that arrester 12 has overheated), controller interface 21 may provide a signal to local controller 22 to activate or deactivate power line switch 23.

Referring to FIG. 2, Controller interface 21 may include a technician interface 26, an arrester failure prediction system 27, and a maintenance scheduling and dispatch interface 28. Controller interface 21 may receive image scheduling information 25 from thermal camera 20. Further Information in an historical arrester database may be retrieved by arrester failure prediction system 27 in controller interface 21. Technician interface 26 may store inputs from a technician to set the levels of the current surge detector before triggering thermal camera 20 or local controller 22. Arrester failure prediction system 27, may include artificial intelligence (Al) based prediction system that with information from historical arrester database 29 analyzes data from the thermal camera 20 and the current surge detector 14 to predict a likelihood of failure of the surge arrester 12, and enhance failure prediction accuracy. Arrester failure prediction system 27 may also analyze the thermal images from thermal camera 20 to detect thermal imbalances indicative of failed MOV disks. Maintenance scheduling and dispatch 28 includes a communication interface to transmit thermal data and failure predictions to a maintenance control center for scheduling preventative maintenance of the surge arrester 12. Maintenance scheduling and dispatch 28 schedules preventative maintenance of the surge arrester 12 based on the transmitted data from to replace or repair the surge arrester prior to complete failure.

The controller interface 21 may additionally or alternatively detect leakage current through the arrester 12 by measuring the leakage current from the current measurement from current surge detector 14 directly and/or by detecting an increase in the temperature of the arrester 12. For leakage current detection, the thermal image of the arrester 12 may be recorded for a relatively short period of time, such as one minute. Even when the leakage current is relatively low, such as on the order of micro Amperes, the temperature of the arrester 12 builds up over time facilitating detection through thermal detection.

In addition, the Maintenance scheduling and dispatch 28 implements preventative maintenance with a remote transmission unit (not shown) that may transmits analysis from the arrester failure prediction system, including thermal recordings or signals based on the thermal recordings to a remote control center (not shown) that schedules preventative maintenance of the arrester 12. The thermal data system facilitates early detection and replacement of the arrester 12 or the faulted MOVs of the arrester prior to the failure of the entire arrester 12.

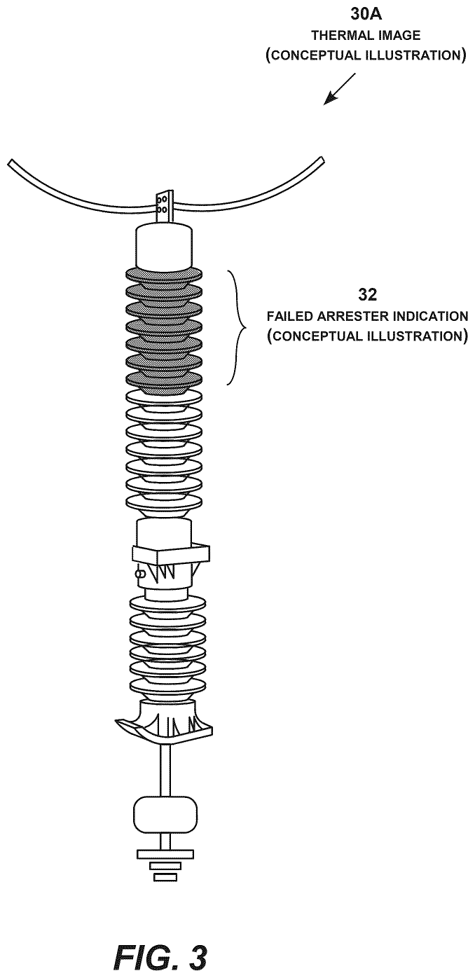

FIG. 3 is a conceptual illustration of a thermal image 30A of a representative of a failed arrester indication 32 on an arrester 12 that may be sensed by thermal camera 20. In this illustration a sequence of multiple MOV's have failed.

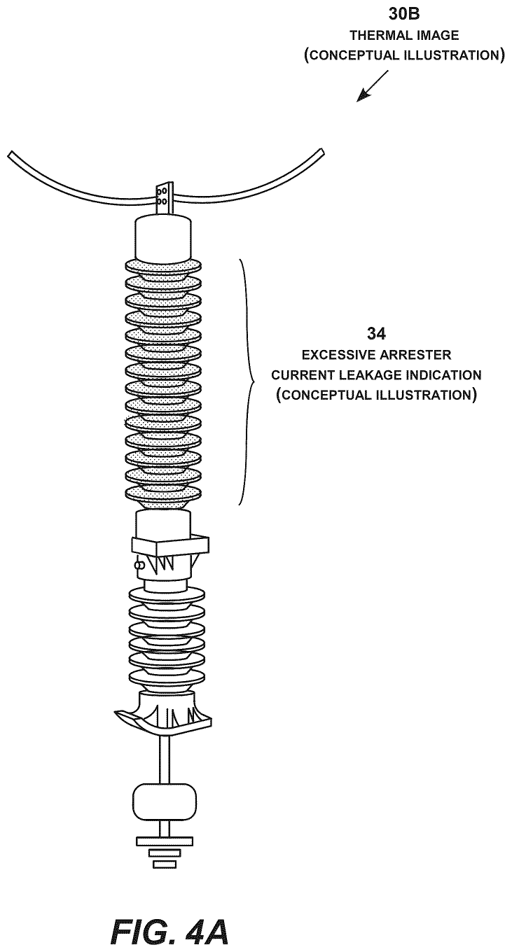

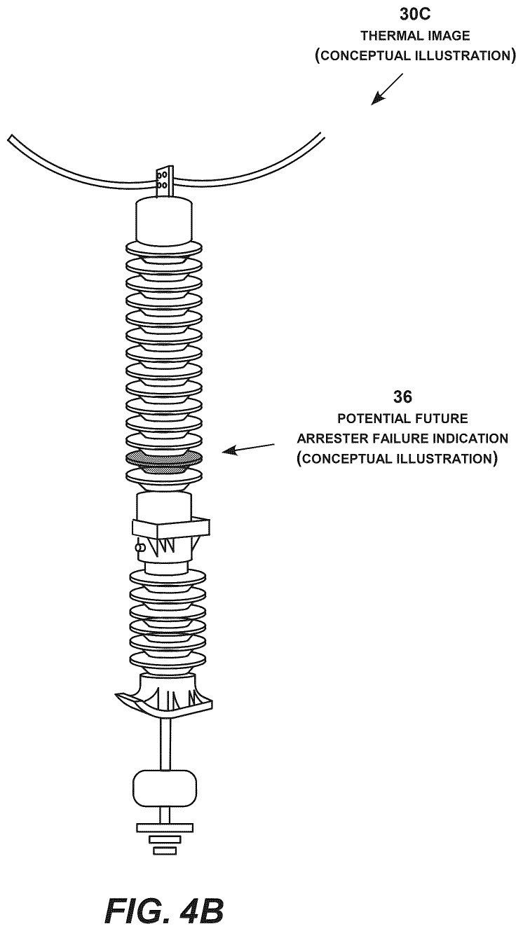

FIG. 4A is a conceptual illustration of a thermal image 30B of a representative of an arrester 12 have a sequence of multiple MOV's with excessive arrester current leak indication. This leakage may be detected by 12 by measuring the leakage current from the current measurement from current surge detector 14 directly and/or by detecting on the arrester an increase in the temperature of the MOVs 34.

FIG. 4B is a conceptual illustration of a thermal image 30C of a representative of a potential future arrester failure indication 36 on an arrester 12 that may be sensed by thermal camera 20. In this illustration a single MOV's is indicating a potential future failure.

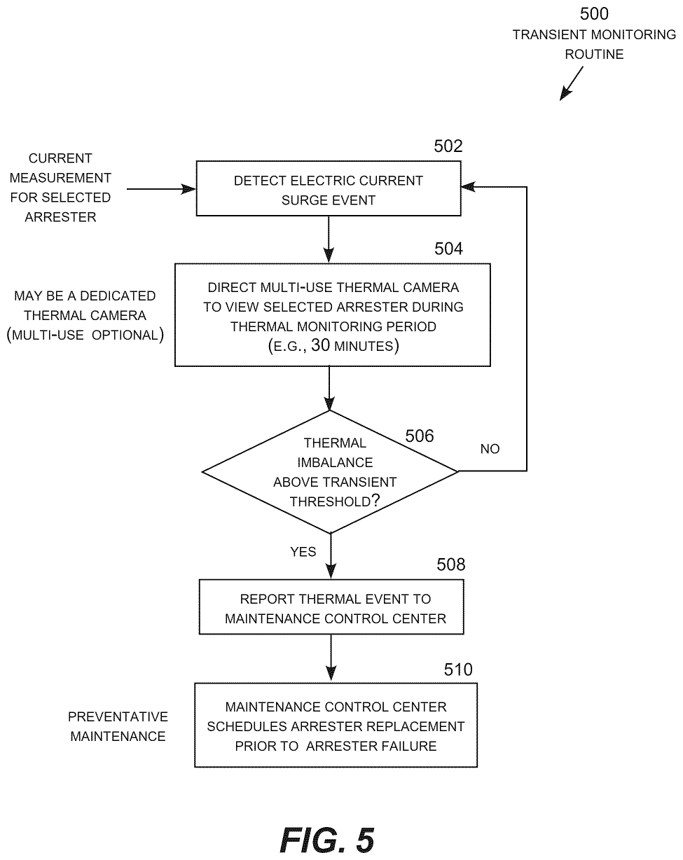

FIG. 5 is a flow chart illustrating a transient monitoring routine 500 implemented by the arrester early fault detection and preventive maintenance system 10. In step 502, the system receives a current measurement for a selected arrester and detects an electric current surge event through the selected arrester. The system may receive current measurements and detect an electric transient event for multiple arresters for any of the monitored arresters. Step 502 is followed by step 504, in which the system directs a multi-use thermal camera to record a thermal image of the selected arrester while it cools down from the surge event. The multi-use thermal camera may be used of other purposes when not responding to transients or capturing thermal images, such as monitoring other arresters, monitoring other pieces of equipment, or surveilling the premises including an area adjacent the surge arrester.

Step 504 is followed by step 506, in which the system determines whether a thermal imbalance above a threshold value has occurred across the surface of the selected arrester indicating one or more failed MOVs of the selected arrester. If a thermal imbalance above the threshold value has not been detected, the “no” branch is followed to step 502, in which the system waits for the detection of an electric current event. If a thermal imbalance above the threshold value has been detected, the “yes” branch is followed to step 508, in which the thermal imbalance event is reported to the maintenance control center, which may conduct additional analyses to predict the likely failure time of the selected arrester based on the thermal data. Ultimately, step 508 is followed by step 510, in which the maintenance control center schedules and dispatches a repair crew to replace or repair the selected arrester prior to failure of the entire arrester. For example, the partially failed selected arrester may be replaced and taken to a repair shop, where one or more failed MOVs are replaced. The repaired arrester can then be returned to service in due course.

System 10 may additionally or alternatively detect a failing arrester by detecting leakage current through one or more arresters. This may be accomplished by measuring the leakage current from the arrester current measurement directly and/or by detecting a slight increase in the temperature of the arrester absent a surge event. For leakage current detection, the thermal image of the arrester may be recorded for a relatively short period of time, such as one minute, periodically in the absence of a current surge event. Even when the leakage current is relatively low, such as on the order of micro-Amperes, the temperature of the arrester builds up over time facilitating leakage detection through thermal detection.

System 10 may optionally receive a current measurement for a selected arrester and detect electric leakage through the selected arrester directly from the monitored current. Even when the leakage current is relatively low, such as on the order of micro-Amperes, the temperature of the arrester 12 builds up over time facilitating leakage detection through thermal detection. Periodic thermal monitoring, as describe ed below, may therefore replace or assist in arrester leakage detection.

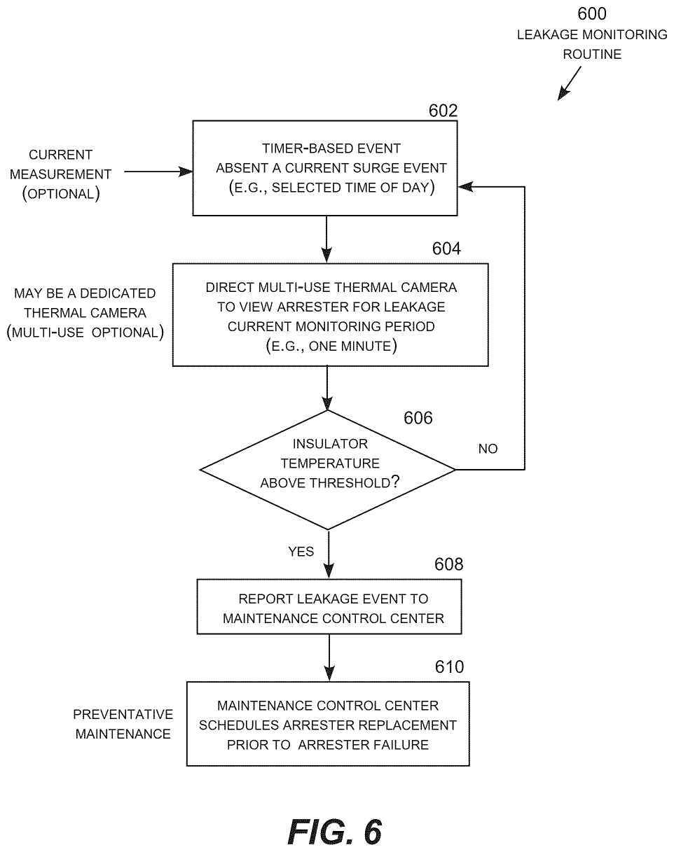

FIG. 6 is a flow chart illustrating a leakage monitoring routine 600 implemented by the arrester early fault detection and preventive maintenance system 10. In step 602, the system periodically conducts leakage monitoring of a selected arrester, provided that an electric current surge event has not tripped the arrester into its electric conducting mode within the previous few hours. When an arrester has not been tripped to conducting mode, the current should be effectively zero. Even a small leakage current on the order of micro-Amperes can indicate a partial failure of one or more MOVs significantly increasing the likelihood of complete failure of the arrester.

Step 602 is followed by step 604, in which the system directs a multi-use thermal camera to record a thermal image of the selected arrester. Because leakage detection is based on the overall temperature of the arrester, the temperature of the selected may be monitored for a relatively short monitoring period, such as one minute. The multi-use thermal camera may be used for other purposes when no responding conducting thermal monitoring of the selected arrester, such as monitoring other arresters, monitoring other pieces of equipment, or surveilling the premises.

Step 604 is followed by step 606, in which the system determines whether an arrester temperature a threshold value above the ambient temperature has occurred indicating one or more failed MOVs of the selected arrester. If an arrester temperature above the threshold value has not been detected, the “no” branch is followed to step 602, in which the system waits for the next monitoring period. If an arrester temperature above the threshold value has been detected, the “yes” branch is followed to step 608, in which the arrester temperature event is reported to the maintenance control center, which may conduct additional analyses to predict the likely failure time of the selected arrester based on the thermal data. Ultimately, step 608 is followed by step 610, in which the maintenance control center schedules and dispatches a repair crew to replace or repair the selected arrester prior to failure of the entire arrester. For example, the partially failed selected arrester may be replaced and taken to a repair shop, where one or more failed MOVs are replaced. The repaired arrester can then be returned to service in due course.

In view of the foregoing, it will be appreciated that present invention provides significant improvements in electric power circuit interrupters utilizing an alternative, more environmentally friendly dielectric gas. The foregoing relates only to the exemplary embodiments of the present invention, and that numerous changes may be made therein without departing from the spirit and scope of the invention as defined by the following claims.

The invention claimed is:

1. An arrester monitoring system, comprising:
a surge arrester including a plurality of metal oxide varistor (MOV) disks;
a current surge detector positioned around a ground wire of the surge arrester, configured to detect current surges and generate an electrical current measurement;
a thermal camera configured to capture thermal images of the surge arrester;
a local controller operatively connected to the current surge detector and the thermal camera, the local controller configured to:
detect a current surge event based on the electrical current measurement;
activate the thermal camera to capture thermal images of the surge arrester in response to the current surge event;
analyze the thermal images to detect thermal imbalances indicative of one or more failed MOV disks; and
an artificial intelligence based failure prediction system configured to analyze data from the thermal camera and the current surge detector to predict a likelihood of failure of the surge arrester; and
a communication interface configured to transmit thermal data and failure predictions to a maintenance control center for scheduling preventative maintenance of the surge arrester.

2. The arrester monitoring system of claim 1, wherein the current surge detector is further configured to detect leakage current through the surge arrester and transmit leakage current data to the local controller.

3. The arrester monitoring system of claim 1, wherein the thermal camera is a multi-use device configured to monitor other equipment or surveil an area adjacent the surge arrester when not capturing thermal images of the surge arrester.

4. The arrester monitoring system of claim 1, wherein the local controller is further configured to measure a temperature of the surge arrester periodically in an absence of a current surge event to detect leakage current.

5. The arrester monitoring system of claim 1, wherein the artificial intelligence based failure prediction system is configured to retrieve historical arrester data from a database to enhance failure prediction accuracy.

6. The arrester monitoring system of claim 1, wherein the communication interface is further configured to transmit thermal recordings or signals based on the thermal recordings to a remote control center for scheduling preventative maintenance.

7. The arrester monitoring system of claim 1, wherein the local controller is further configured to activate or deactivate a power line switch in response to detecting an overheated surge arrester.

8. A substation for an electric power system, comprising:
protective equipment including a surge arrester having a plurality of metal oxide varistor (MOV) disks;
a current surge detector positioned around a ground wire of the surge arrester, configured to detect current surges and generate a current measurement;
a thermal camera configured to capture thermal images of the surge arrester;
a local controller operatively connected to the current surge detector and the thermal camera, the local controller configured to:
detect a current surge event based on the current measurement;
activate the thermal camera to capture thermal images of the surge arrester in response to the current surge event; and
analyze with an artificial intelligence based failure prediction system the thermal images to detect thermal imbalances indicative of failed or failing MOV disks and a current surge detector to predict a likelihood of failure of the surge arrester; and
a ground grid configured to safely discharge excess energy from the surge arrester into ground.

9. The substation of claim 8, wherein the current surge detector is further configured to detect leakage current through the surge arrester and transmit leakage current data to the local controller.

10. The substation of claim 8, wherein the thermal camera is a multi-use device configured to monitor other equipment or surveil an area around the surge arrester when not capturing thermal images of the surge arrester.

11. The substation of claim 8, wherein the local controller is further configured to measure a temperature of the surge arrester periodically in an absence of a current surge event to detect leakage current.

12. The substation of claim 8, wherein the artificial intelligence based failure prediction system is configured to retrieve historical arrester data from a database to enhance failure prediction accuracy.

13. The substation of claim 8, further comprising a communication interface configured to transmit thermal recordings or signals based on the thermal recordings to a remote control center for scheduling preventative maintenance.

14. A method for operating an arrester monitoring and maintenance system, comprising:
providing a surge arrester including a plurality of metal oxide varistor (MOV) disks;
detecting a current surge event through the surge arrester using a current surge detector positioned around a ground wire of the surge arrester;
activating a thermal camera to capture thermal images of the surge arrester in response to the current surge event;
analyzing with an artificial intelligence based failure prediction system the thermal images and a current surge detector to obtain thermal data and failure predictions of the surge arrester;
transmitting the thermal data and failure predictions to a maintenance control center; and
scheduling preventative maintenance of the surge arrester based on the transmitted failure predictions to replace or repair the surge arrester prior to complete failure.

15. The method of claim 14, further comprising detecting leakage current through the surge arrester using the current surge detector and transmitting leakage current data to a local controller.

16. The method of claim 14, further comprising using the thermal camera as a multi-use device to monitor other equipment or surveil ground adjacent the surge arrester when not capturing thermal images of the surge arrester.

17. The method of claim 14, further comprising periodically measuring temperature of the surge arrester in an absence of a current surge event to detect leakage current.

18. The method of claim 14, further comprising retrieving historical arrester data from a database to enhance failure prediction accuracy using an artificial intelligence based failure prediction system.

19. The method of claim 14, further comprising transmitting thermal recordings or signals based on the thermal recordings to a remote control center for scheduling preventative maintenance.

20. The method of claim 14, further comprising activating or deactivating a power line switch in response to detecting an overheated surge arrester.
